(19) United States
(12) Patent Application Publication
(10) Pub. No.: US 2016/0211158 A1
(43) Pub. Date: Jul. 21, 2016

(54) Tank switch and method of monitoring a fluid rate

(71) Applicant: Infineon Technologies AG, Neubiberg (DE)

(72) Inventors: Choon Joo Samuel YEOW, Singapore (SG); Jee Liang TAN, Singapore (SG)

(21) Appl. No.: 14/997,598

(22) Filed: Jan. 18, 2016

(30) Foreign Application Priority Data
Jan. 20, 2015 (DE) 10 2015 100 762.2

(51) Int. Cl. H01L 21/67; G05D 16/20; F16K 17/00; G01F 1/00; F16K 15/00

(52) U.S. Cl. CPC H01L 21/67253; G01F 1/00; F16K 15/00; F16K 17/00; G05D 16/20

(57) ABSTRACT

A tank switch for a semiconductor test system is provided, wherein the tank switch comprises a manifold comprising a first input pipe, a second input pipe, an output pipe and an flow sensor, wherein each of the input pipes is configured to be connected to a respective fluid tank and the output pipe comprises an output terminal which is configured to be connected to a testing handler, wherein each of the input pipes comprises a respective control valve; wherein the flow sensor is built into the manifold before the output terminal and is configured to provide a measurement signal indicative of the flow rate of a fluid through output terminal and to send the signal to a control unit; and wherein each of the control valves is configured to receive a control signal and to be opened or closed responsive to the received control signal.

### TECHNICAL FIELD

Various embodiments relate to a tank switch, a system for supplying fluid, and a method of monitoring a fluid rate in a semiconductor test system.

### BACKGROUND

Finished semiconductors are often tested for function after the semiconductors are manufactured. For performing these tests, often test systems are used including a handler configured for handling the semiconductor or devices under test. Furthermore, cold temperature tests procedures are often performed in order to test the semiconductor (e.g. transistors or power transistors) as well under cold temperatures. For providing the cooling (energy) fluids like liquid gas (e.g. liquid air or liquid nitrogen) are generally used and provided by a liquid gas cylinder and a pipe or tube system. In order to provide for a continuous fluid supply a tank switch is used to which at least two liquid gas cylinder are connected, which provide alternatively cooling fluid to the tank switch and the handler connected thereto.

### SUMMARY

Various embodiments provide a tank switch for a semiconductor test system, wherein the tank switch comprises a manifold comprising a first input pipe, a second input pipe, an output pipe and an flow sensor, wherein each of the input pipes is configured to be connected to a respective fluid tank and the output pipe comprises an output terminal which is configured to be connected to a testing handler, wherein each of the input pipes comprises a respective control valve; wherein the flow sensor is built into the manifold before the output terminal and is configured to provide a measurement signal indicative of the flow rate of a fluid through output terminal and to send the signal to a control unit; and wherein each of the control valves is configured to receive a control signal and to be opened or closed responsive to the received control signal.

Furthermore, various embodiments provide a semiconductor test system comprising a tank switch, a test handler comprising an input terminal connected to the output terminal of the tank switch; and a control unit configured to receive the measurement signal of the flow sensor and to provide a control signal to the control valves.

Moreover, various embodiments provide a method of monitoring a fluid rate in a semiconductor test system, wherein the method comprises supplying a fluid through an input pipe and an output pipe from a fluid tank to a handler; measuring a flow rate of the supplied fluid by a flow sensor; generating a measurement signal indicative of the measured flow rate; and directing the measurement signal to a control unit.

### BRIEF DESCRIPTION OF THE DRAWINGS

In the drawings, like reference characters generally refer to the same parts throughout the different views. The drawings are not necessarily to scale. Instead emphasis is generally being placed upon illustrating the principles of the invention. In the following description, various embodiments are described with reference to the following drawings, in which:

FIG. 1 schematically illustrates a tank switch according to an exemplary embodiment;

FIG. 2 schematically illustrates a semiconductor test system according to an exemplary embodiment;

FIG. 3 depicts a flowchart of a method of monitoring a fluid rate according to an exemplary embodiment; and

FIG. 4 schematically illustrates a semiconductor test system according to an exemplary embodiment.

### DETAILED DESCRIPTION

In the following further exemplary embodiments of a tank switch, a system for supplying fluid, and a method of monitoring a fluid rate in a semiconductor test system will be explained. It should be noted that the description of specific features described in the context of one specific exemplary embodiment may be combined with others exemplary embodiments as well.

The word “exemplary” is used herein to mean “serving as an example, instance, or illustration”. Any embodiment or design described herein as “exemplary” is not necessarily to be construed as preferred or advantageous over other embodiments or designs.

Various exemplary embodiments provide a tank switch for a semiconductor test system the tank switch comprises a manifold comprising two input pipes and an output pipe, wherein a fluid flow path is formed by at least one of the input pipes and the output pipe, wherein a respective control valve is built in each input pipe and at least one flow sensor is built in the fluid path, wherein the flow sensor is adapted to measure a flow rate, to generate a measurement signal indicative of the measured flow rate and to send the measurement signal to a control unit. Furthermore, each of the control valves is adapted to receive a control signal from the control unit and to be opened or closed depending on the control signal.

In particular, the fluid flow is directed or guided from an input terminal (e.g. configured to be coupled to a fluid tank) to an output terminal (e.g. configured to be coupled to a test handler) of the output pipe. In particular, a single flow sensor may be built in the output pipe (while a first control valve may be incorporated in the first input pipe and a second control valve may be incorporated in the second input pipe) and/or a first flow sensor and a first control valve may be built or incorporated in the first input pipe and a second flow sensor and a second control valve is build or incorporated in the second input pipe. The flow sensor(s), may monitor and control, respectively the fluid flow through the input pipes. In particular, the control valve may be a solenoid valve or any other kind of valve which can be used at different (cold) temperature levels. It should be noted that of course more than two input pipes may be provided implemented in one tank switch and thus more than two tanks may be connected and controlled by the tank switch.

In particular, the control unit, e.g. a PLC controller, may comprise a computing or processing unit configured to determine an actual flow rate of the fluid out of the received measurement signal and/or to determine whether the flow rate is above or below the predetermined threshold value. Based on this determination or calculation the control unit may generate the control signal. The control signal may in particular indicate that a control valve receiving the control signal is to be switched on or off. In particular, the control valve may be configured to switch off or on depending on the received control signal. In particular, the input pipes and/or the output pipes may comprise or may consist of a plastic material and/or metal material, e.g. steel or the like.

The term “input pipe” may particularly denote a pipe or tube of the manifold starting from an input terminal (configured to be connected to a fluid tank) to a junction at which the one input pipe connects to another input pipe. The term “output pipe” may particularly denote a pipe or tube of the manifold starting from that junction point to an output terminal (configured to be connected to a test handler).

By providing a tank switch comprising a flow sensor or meter instead of another sensor (like a pressure sensor) it may be possible to enable a more flexible control and more direct control of a fluid (e.g. cooling fluid) supply. For example, it may be possible to perform test procedures at different pressure levels in an easy and efficient way when compared to a pressure controlled switch. It may even be possible to use different types of (test) handlers in an easy way with the test switch. In particular, it may be possible to more closely adapt or set a limit or threshold of the provided fluid, since directly the amount of the provided fluid is controlled and not indirect by determining a pressure, for example. In particular, the tank switch may enable an automatic switching between different liquid gas tanks or containers. Thus, it may not be necessary any more to use control cards or the like to manage a manual operation switching between different tanks. Furthermore, the automatic switching may allow for a sufficient time for a change over between the different fluid tanks.

This direct fluid amount control may in particular, be advantageous when different test handlers adapted for different semiconductors are used in connection with the tank switch, since every test handler may need a different amount of fluid per time period, i.e. fluid rate. Thus, it may be possible to improve an overall equipment efficiency, while at the same time possibly improving or at least not reducing a temperature stability and/or product quality during a testing procedure. Furthermore, the use of a tank switch including a flow sensor may enable an efficient level and/or consumption monitoring.

In the following exemplary embodiments of the tank switch are described. However, the features and elements described with respect to these embodiments can be combined with exemplary embodiments of the system for supplying fluids, and a method of monitoring a fluid rate in a semiconductor test system.

According to an exemplary embodiment the tank switch further comprises at least one further element selected out of the group consisting of a relief valve, a pressure gauge, and a check-valve.

All of these elements may be used as security features increasing the safety of the tank switch or the whole system in which the tank switch is used.

According to an exemplary embodiment the tank switch further comprises a signal interface.

In particular, the signal interface may be an Ethernet interface and/or may enable an Ethernet connection. For example, the signal provided by the flow sensor may be configured to be communicated or sent via the signal interface, e.g. an Ethernet interface.

According to an exemplary embodiment of the tank switch an insulation layer is arranged around the input pipes and the output pipe.

The provision of an insulation layer or sleeve, e.g. formed by a foam material or an additional outer or sleeve layer, may ensure that a temperature of the fluid may substantially not change during its flowing through the input and output pipes. Additional it may reduce the forming or developing of condensation water at the outer surface of the pipes.

According to an exemplary embodiment of the tank switch the flow sensor is built in the output pipe.

By arranging the flow sensor in the output pipe and not in an input pipe it may be possible to just use a single flow sensor for the overall system independent of the number of input pipes and corresponding connected fluid tanks. As long as only one fluid tank supplies the fluid (i.e. only the respective control valve is open) the value measured by the one flow sensor will correspond to the respective input pipe.

According to an exemplary embodiment the tank switch further comprises a further flow sensor which is configured to provide a measurement signal indicative of the flow rate of the fluid, wherein the flow sensor is built in the first input pipe and the further flow sensor is built in the second input pipe.

By using two flow sensors (or one flow sensor per input valve in case of more than two input pipes are used) it may be possible to monitor and control the fluid flow more flexible. For example, more than one control valve may be opened at a time but it may still be possible to monitor each input pipe (and corresponding fluid tank) independently.

In the following exemplary embodiments of the system for supplying fluid are described. However, the features and elements described with respect to these embodiments can be combined with exemplary embodiments of the tank switch, and a method of monitoring a fluid rate in a semiconductor test system.

According to an exemplary embodiment of the semiconductor test system the control unit is configured to provide the control signal in case the control unit determines that the measurement signal of the flow sensor indicates that the fluid flow is below a predetermined threshold.

However, it should be noted that the fluid flow is still above zero, i.e. the control valve is open and the fluid tank connected to the respective input pipe is not completely empty yet. That is, the flow sensor may measure that the flow rate is in an interval limited by a value greater than zero and by the predetermined threshold. It should be mentioned that the predetermined threshold value may of course depend on the test performed and/or the semiconductor tested by the test. Thus, it may not possible to give an absolute value of the predetermined threshold value but for every application it may be easily calculated and/or determined by a person skilled in the art depending on the amount of cooling fluid needed. In particular, the threshold value may be defined by the intended cooling action needed or desired for a given test procedure.

For example, in case the fluid is a cooling fluid, like liquid air or liquid nitrogen, the predetermined threshold value (and thus the amount of fluid) may depend on the amount of cooling energy or cryogenic energy or cooling fluid needed to reach an intended temperature. Thus, it may as well depend on the temperature of the environment the test system is used in, the number of semiconductors tested, the amount of heat produced during the test and the like. However, a person skilled in the art may clearly and easily determine such a predetermined threshold.

According to an exemplary embodiment of the semiconductor test system the control signal is provided to both control valves.

In particular, the control signal may be configured to close one control valve while it is as well configured to open the other control valve. The control signal may thus be formed by two sub control signals, one representing an open or on control signal, and the other one representing a close or off control signal. Thus, it may be possible to close one control valve while at the same time or with the same control signal to open the other control valve. Therefore, the tank providing or supplying the fluid to the output pipe is changed or switched.

According to an exemplary embodiment of the semiconductor test system the control signal is an off control signal and is provided to the open control valve.

In particular, the open control valve may correspond or built in the (or one of the) input pipe(s) which supply actually fluid to the output terminal, i.e. which is open and not closed. That is, in case of the use of two input pipes and two flow sensors, the one of the two flow sensors is the one measuring a flow rate below the predetermined threshold. In particular, the control signal and/or the control valve is configured to be switched off in case it receives the of control signal.

According to an exemplary embodiment of the semiconductor test system the control signal is an on control signal and is provided to a closed control valve.

According to an exemplary embodiment the semiconductor test system further comprises two fluid tanks each coupled to a respective one of the input pipes of the tank switch.

According to an exemplary embodiment the semiconductor test system further comprises a display configured to display a filling level of at least one of the fluid tanks.

In particular, the control unit may be configured to determine the filling level to be displayed from a received measurement signal. Thus, it may be possible to visually indicate an actual filling level status. For example, the display may be a part of the control unit or may be a separate unit.

In the following exemplary embodiments of the method of monitoring a fluid rate in a semiconductor test system are described. However, the features and elements described with respect to these embodiments can be combined with exemplary embodiments of the tank switch, and the system for supplying a fluid.

According to an exemplary embodiment the method further comprises determining whether the measurement signal indicates a flow rate below a predetermined threshold; and generating a control signal in case it is determined that the determined flow rate is below the predetermined threshold.

According to an exemplary embodiment the method further comprises sending the control signal to a control valve built in the input pipe.

In particular, the control signal is a switch off signal. Thus, the control valve receiving the control signal may be switched off. Therefore, the respective input pipe may be closed so that a fluid tank connected to the input pipe associated with the control valve is decoupled from an output pipe of the semiconductor test system. Of course another control signal may be sent to the second control valve to open the same so that the respective input pipe may be used to supply fluid to the output pipe.

In the following specific embodiments of the tank switch, the system for supplying fluid, and the method of monitoring a fluid rate in a semiconductor test system will be described in more detail with respect to the figures.

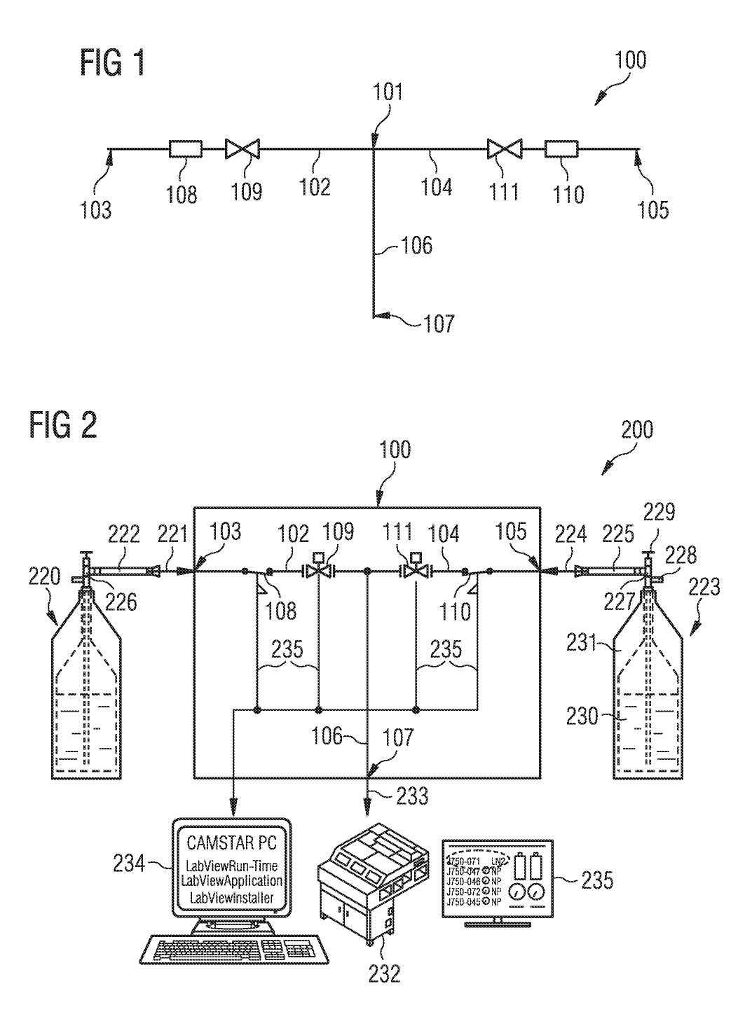

FIG. 1 schematically illustrates a tank switch 100 according to an exemplary embodiment. In particular, FIG. 1 shows a manifold 101 comprising a first input pipe or tube 102 having an input terminal 103, a second input pipe 104 having an input terminal 105, and an output pipe 106 having an output terminal 107. While the input terminals may be connected or coupled to a respective fluid tank, e.g. a liquid gas cylinder, the output terminal may be connected to a (test) handler, configured to perform test procedures with semiconductors to be tested. It should be noted that the manifold 101 may of course comprise more than two input pipes and/or may as well comprise more than one output pipe. However, preferably only one output pipe is provided.

In the fluid path formed by the first input pipe 102 a first flow sensor or flow meter 108 is included configured to measure a flow rate of fluid flowing through the first input pipe 102 and send a respective measurement signal to a control unit. Furthermore, a first control valve, e.g. a (cryogenic) solenoid valve, 109 is included in the first input pipe 102 as well and is configured to receive a control signal from the control unit and to be closed or opened responsive to the control signal.

In the fluid path formed by the second input pipe 104 a second flow sensor or flow meter 110 is included and is configured to measure a flow rate of fluid flowing through the second input pipe 102 and send a respective measurement signal to the control unit. Furthermore, a second control valve, e.g. a solenoid valve, 111 is included in the first input pipe 104 as well and is configured to receive a control signal from the control unit and to be closed or opened responsive to the control signal.

FIG. 2 schematically illustrates a semiconductor test system 200 according to an exemplary embodiment. In particular, the semiconductor test system 200 comprises a test switch 100 (as described with reference to FIG. 1). The input terminal 103 of the first input pipe 102 is connected to a first liquid air or liquid nitrogen tank 220 via a first pipe section 221 and a flexible connector 222. At the same time the input terminal 105 of the second input pipe 104 is connected to a second liquid air tank 223 via a second pipe section 224 and a flexible connector 225.

In particular, the flexible connectors 222 and 225 are connected to a respective pressure gauge 226 and 227, respectively. In addition, the tanks comprise a ventilation valve 228 and a transfer valve 229 and are filled with liquid nitrogen 230 (indicated by the lines in the fluid tank). Further, the tanks comprise a vacuum jacket 231 to provide a thermal isolation.

Furthermore, the semiconductor test system 200 comprises a handler 232 for providing or performing the actual testing of the semiconductors to be tested. The handler 232 is connected to the output terminal 107 of output pipe 106 which is schematically indicated in FIG. 2 by arrow 233.

Moreover, the semiconductor test system 200 comprises a control unit 234, e.g. a processor or computing unit, which is electrically connected to both flow sensors and control valves as indicated by lines 235. The control unit is configured to determine an actual flow rate from measurement signals provided by the flow sensors 108 and 110, respectively. Based on the determined actual flow rate the control unit can decide whether a control valve shall be switched off or on in order to provide a continuous flow of cooling fluid to the handler.

For example, in case the actual flow rate through the first input pipe to the output pipe falls below a predetermined threshold, e.g. defined by a sufficient or desired cooling rate, the control unit may generate a control signal forwarded to the first control valve 109 indicating that the same shall be closed (so that the respective fluid tank can be changed, i.e. a full new tank may be connected to the input terminal 103). At the same time another (or the same) control signal, can be sent to the second control valve 111 indicating that the same shall be opened so that cooling fluid is provided from the second tank to the output pipe and the handler, e.g. forms the active tank.

In addition the semiconductor test system 200 may comprise a display 236 for displaying the status of the semiconductor test system 200, e.g. which control valve is open and/or the actual flow rate and/or the filling level of the active tank. The display 236 may be formed by a separate device or unit or may be part of the control unit 234.

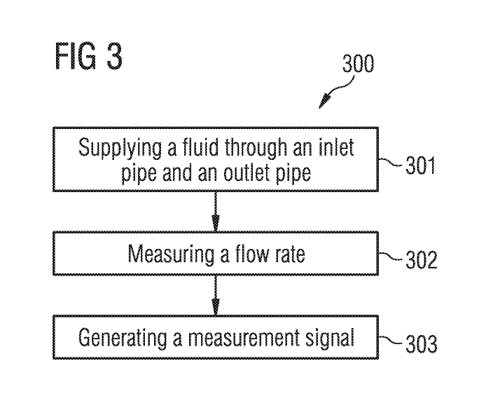

FIG. 3 depicts a flowchart of a method of monitoring a fluid rate 300 according to an exemplary embodiment. In particular, the method comprises supplying a fluid through an input pipe and an output pipe (step 301). The fluid, e.g. a cooling fluid, may be provided from a fluid tank to a handler or test handler usable for a testing process of semiconductors. During the supplying the actual flow rate of the fluid in the input pipe (and thus to the output pipe, in case substantially no loss of fluid occur) is measured by a flow sensor built in the input pipe (step 302). From this measured flow rate a measurement signal is generated being indicative of the actual flow rate (step 303).

Optionally the method may further comprise a determining step in which it is determined whether the measurement signal indicates a flow rate below a predetermined threshold, which step may be followed by a generating of a control signal in case it is determined that the determined flow rate is below the predetermined threshold. Thus, a control signal based on a measured actual fluid flow may be generated which can be used to control or switch the control valves and thus the fluid flow through the respective input pipes.

The generated control signal may be sent to the respective control valves for controlling the same, e.g. turn one on while the other one is turned off. In particular, the control valve associated with an input pipe and fluid tank which has a low level of fluid may be turned off so that the respective tank (having the low level) may be replaced by a full tank which is connected to the respective input terminal of the tank switch.

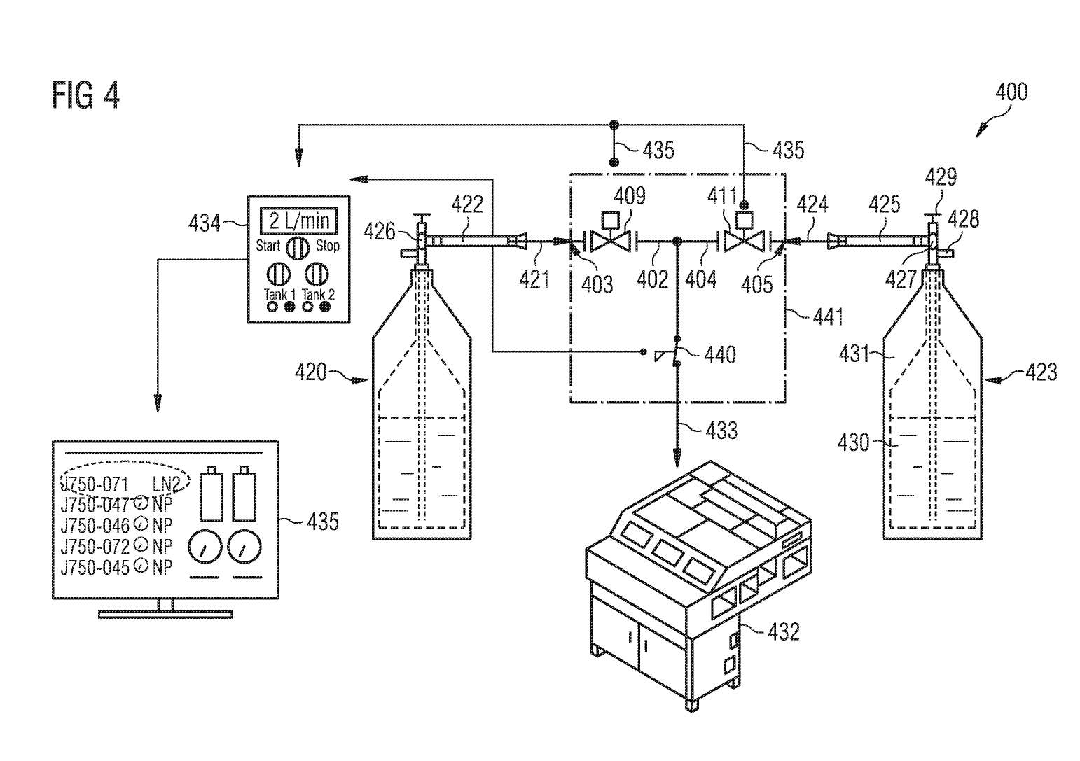

FIG. 4 schematically illustrates a semiconductor test system according to another exemplary embodiment. In particular, the semiconductor test system 400 is similar to the one depicted in FIG. 2. However, instead of the two flow sensors (one in each of the depicted input pipes) in the embodiment of FIG. 2 only one single flow sensor 440 is built in or arranged in an output pipe 406 in the embodiment of FIG. 4. In more detail semiconductor test system 400 comprises a test switch 441. The input terminal 403 of the first input pipe 402 is connected to a first liquid air or liquid nitrogen tank 420 via a first pipe section 421 and a flexible connector 422. At the same time the input terminal 405 of the second input pipe 404 is connected to a second liquid air tank 423 via a second pipe section 424 and a flexible connector 425.

In particular, the flexible connectors 422 and 425 are connected to a respective pressure gauge 426 and 427, respectively. In addition, the tanks comprise a ventilation valve 428 and a transfer valve 429 and are filled with liquid nitrogen 430 (indicated by the lines in the fluid tank). Further, the tanks comprise a vacuum jacket 431 to provide a thermal isolation.

Furthermore, the semiconductor test system 400 comprises a handler 432 for providing or performing the actual testing of the semiconductors to be tested. The handler 432 is connected to the output terminal 407 of output pipe 406 which is schematically indicated in FIG. 4 by arrow 433.

Moreover, the semiconductor test system 400 comprises a control unit 434, e.g. a processor or computing unit, which is electrically connected to the flow sensor and the control valves as indicated by lines 435. The control unit is configured to determine an actual flow rate from measurement signals provided by the flow sensor 440 arranged in the output pipe 406 before the output terminal 407. Based on the determined actual flow rate the control unit can decide whether a control valve shall be switched off or on in order to provide a continuous flow of cooling fluid to the handler.

For example, in case the actual flow rate through the output pipe to the output terminal falls below a predetermined threshold, e.g. defined by a sufficient or desired cooling rate, the control unit may generate a control signal forwarded to the control valve which is actually open and indicating that the same shall be closed (so that the respective fluid tank can be changed, i.e. a full new tank may be connected to the respective input terminal). At the same time another (or the same) control signal, can be sent to the other control valve (which is actually closed) indicating that the same shall be opened (so that cooling fluid is provided from the respective fluid tank to the output pipe and the handler, e.g. forms the active tank).

In addition the semiconductor test system 400 may comprise a display 436 for displaying the status of the semiconductor test system 400, e.g. which control valve is open and/or the actual flow rate and/or the filling level of the active tank. The display 436 may be formed by a separate device or unit or may be part of the control unit 434.

It should also be noted that the term “comprising” does not exclude other elements or features and the “a” or “an” does not exclude a plurality. Also elements described in association with different embodiments may be combined. It should also be noted that reference signs shall not be construed as limiting the scope of the claims. While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A tank switch for a semiconductor test system, the tank switch comprising:
a manifold comprising a first input pipe, a second input pipe and an output pipe, wherein each of the input pipes is configured to be connected to a respective fluid tank and the output pipe comprising an output terminal which is configured to be connected to a testing handler,
wherein each of the input pipes comprises a respective control valve;
wherein a flow sensor is built in the manifold before the output terminal;
wherein the flow sensor is configured to provide a measurement signal indicative of the flow rate of a fluid to the output terminal and to send the signal to a control unit; and
wherein each of the control valves is configured to receive a control signal and to be opened or closed responsive to the received control signal.

2. The tank switch according to claim 1, further comprising at least one further element selected out of the group consisting of:
a relief valve,
a pressure gauge, and
a check-valve.

3. The tank switch according to claim 1, further comprising a signal interface.

4. The tank switch according to claim 1, further comprising an insulation layer arranged around the input pipes and the output pipe.

5. The tank switch according to claim 1, wherein the flow sensor is built in the output pipe.

6. The tank switch according to claim 1, further comprising a further flow sensor which is configured to provide a measurement signal indicative of the flow rate of the fluid, wherein the flow sensor is built in the first input pipe and the further flow sensor is built in the second input pipe.

7. A semiconductor test system comprising:
a tank switch according to claim 1;
a test handler comprising an input terminal connected to the output terminal of the tank switch; and
a control unit configured to receive the measurement signal of the flow sensor and to provide a control signal to the control valves.

8. The semiconductor test system according to claim 7, wherein the control unit is configured to provide the control signal in case the control unit determines that the measurement signal of the flow sensor indicates that the fluid flow is below a predetermined threshold.

9. The semiconductor test system according to claim 8, wherein the control signal is provided to both control valves.

10. The semiconductor test system according to claim 8, wherein the control signal is an off control signal and is provided to the open control valve.

11. The semiconductor test system according to claim 8, wherein the control signal is an on control signal and is provided to a closed control valve.

12. The semiconductor test system according to claim 7, further comprising two fluid tanks each coupled to a respective one of the input pipes of the tank switch.

13. The semiconductor test system according to claim 12, further comprising a display configured to display a filling level of at least one of the fluid tanks.

14. A method of monitoring a fluid rate in a semiconductor test system, the method comprising:
supplying a fluid through an input pipe and an output pipe from a fluid tank to a handler;
measuring a flow rate of the fluid by a flow sensor; and
generating a measurement signal indicative of the measured flow rate.

15. The method according to claim 14, further comprising:
determining whether the measurement signal indicates a flow rate below a predetermined threshold; and
generating a control signal in case it is determined that the determined flow rate is below the predetermined threshold.

16. The method according to claim 15, further comprising:
sending the control signal to a control valve built in the input pipe.
